(19) United States
(12) Patent Application Publication
(10) Pub. No.: US 2026/0011576 A1
(43) Pub. Date: Jan. 8, 2026

(54) PARTICLE DEFECT PREDICTION AND CORRECTION BASED ON PROCESS CHAMBER MODELING

(71) Applicant: Applied Materials, Inc., Santa Clara, CA (US)

(72) Inventors: Devi Raghavee Veerappan, Nijmegen (NL); Chezheng Cao, Sunnyvale, CA (US)

(21) Appl. No.: 18/766,487

(22) Filed: Jul. 8, 2024

(51) Int. Cl. H01L 21/67; G06N 3/045; H01L 21/687

(52) U.S. Cl. CPC H01L 21/67017; G06N 3/045; H01L 21/67207; H01L 21/68714

(57) ABSTRACT

A method includes providing initial process conditions to a model associated with a process chamber. The method further includes providing an indication of one or more adjustments to the process chamber resulting in final process conditions to the model. The method further includes obtaining an indication of first gas backflow to a substrate support of the process chamber from the model. The method further includes generating updated one or more adjustments to the process chamber. The method further includes providing an indication of the updated one or more adjustments to the model. The method further includes obtaining from the model an indication of second gas backflow to the substrate support. The method further includes performing a corrective action based on the updated one or more adjustments.

### TECHNICAL FIELD

The present disclosure relates to methods associated with predicting and correcting particle defects in substrate processing. Specifically, the present disclosure related to particle defect prediction and correction based on process chamber modeling.

### BACKGROUND

Products may be produced by performing one or more manufacturing processes using manufacturing equipment. For example, semiconductor manufacturing equipment may be used to produce substrates via semiconductor manufacturing processes. Products are to be produced with particular properties, suited for a target application. Product properties may include repeatability, e.g., freedom of products from defects. Machine learning models are used in various process control and predictive functions associated with manufacturing equipment. Machine learning models are trained using data associated with the manufacturing equipment. Output of machine learning models may be associated with the generation of substrate defects.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In one aspect of the present disclosure, a method includes providing initial process conditions to a model associated with a process chamber. The method further includes providing an indication of one or more adjustments to the process chamber resulting in final process conditions to the model. The method further includes obtaining an indication of first gas backflow to a substrate support of the process chamber from the model. The method further includes generating updated one or more adjustments to the process chamber. The method further includes providing an indication of the updated one or more adjustments to the model. The method further includes obtaining from the model an indication of second gas backflow to the substrate support. The method further includes performing a corrective action based on the updated one or more adjustments.

In another aspect of the disclosure, a method includes obtaining a plurality of initial process conditions associated with a process chamber. The method further includes obtaining a plurality of process chamber adjustments. The method further includes obtaining a plurality of backflow data, each backflow data associated with one of the initial process conditions and one of the process chamber adjustments. The method further includes training a machine learning model to predict gas backflow by providing the plurality of initial process conditions and plurality of process chamber adjustments as training input, and the plurality of backflow data as target output.

In another aspect of the disclosure, a non-transitory machine-readable storage medium is disclosed. The storage medium stores instructions which, when executed, cause a processing device to perform operations. The operations include providing initial process conditions to a model associated with a process chamber. The operations further include providing an indication of one or more adjustments to the process chamber resulting in final process conditions to the model. The operations further include obtaining an indication of first gas backflow to a substrate support of the process chamber from the model. The operations further include generating updated one or more adjustments to the process chamber. The operations further include providing an indication of the updated one or more adjustments to the model. The operations further include obtaining from the model an indication of second gas backflow to the substrate support. The operations further include performing a corrective action based on the updated one or more adjustments.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to some embodiments.

FIG. 2 depicts a block diagram of a system including an example data set generator for creating data sets for one or more supervised models, according to some embodiments.

FIG. 3 is a block diagram illustrating a system for generating output data, according to some embodiments.

FIG. 4A is a flow diagram of a method for generating a data set for a machine learning model, according to some embodiments.

FIG. 4B is a flow diagram of a method for utilizing a model for predicting and/or correcting a particle defect root cause of a substrate processing system, according to some embodiments.

FIG. 4C is a flow diagram of a method for correcting one or more substrate defect root causes, according to some embodiments.

FIG. 4D is a flow diagram of a method for generating a trained machine learning model for performing operations in association with particle defects of a substrate processing system, according to some embodiments.

FIG. 4E is a flow diagram for an example method for using a model to adjust operations of a process chamber, according to some embodiments.

FIG. 5 depicts a sectional view of a processing chamber that may be modeled for determining predictive data in association with particle defects, according to some embodiments.

FIG. 6 is a block diagram illustrating a computer system, according to some embodiments.

### DETAILED DESCRIPTION

Described herein are technologies related to improving processes of substrate manufacturing by reducing substrate defects. Manufacturing equipment is used to produce products, such as substrates (e.g., wafers, semiconductors). Manufacturing equipment may include a manufacturing or processing chamber to separate the substrate from the environment. The properties of produced substrates are to meet target values to facilitate specific functionalities. Manufacturing parameters are selected to produce substrates that meet the target property values. Many manufacturing parameters (e.g., hardware parameters, process parameters, etc.) contribute to the properties of processed substrates. Manufacturing systems may control parameters by specifying a set point for a property value and receiving data from sensors disposed within the manufacturing chamber, and making adjustments to the manufacturing equipment until the sensor readings match the set point. Adjustments made to the manufacturing equipment may be made based on one or more metrics. For example, a change in gas flow or pressure may be performed by adjusting a valve, and a speed of adjustment of the valve may be controlled by one or more control parameters in association with the process recipe, the process chamber, or the like.

Various types of models may be applied in several ways associated with processing chambers and/or manufacturing equipment. Models applicable to a process chamber may include a physics-based model, a digital twin model, a statistical model, a machine learning model, or the like.

In some systems, substrate defects may occur during processing. The substrate defects may occur in connection with one or more of process parameters (e.g., process recipe), hardware parameters (e.g., process tool equipment constants), installed hardware components, chamber chemistry, or other constraints affecting substrate processing operations. It may be the focus of considerable effort to analyze root causes of defects, predict defect formation, and correct defect sources to improve consistency of substrate processing procedures.

Defects may be of various types (e.g., pits, scratches, particles, etc.), be provided from various sources, be related to various procedures, or the like. In some systems, particle defects may be a concern. A particle defect may occur when a particle of material is liberated from some location of a processing system, and falls onto a substrate undergoing processing, which may impact substrate performance, interrupt or interfere with further process operations performed on the substrate, etc.

In some systems, particle defects may be introduced to a substrate by gas flow directing a particle from one region of a process chamber to a region proximate the substrate. For example, gas flow may draw a particle from a particle source to the substrate, and deposit the particle on the substrate, forming a particle defect on the substrate. In some embodiments one or more actions of the substrate processing system may cause gas flow directing particles toward the substrate.

In some systems, one or more actions may be taken by the processing system, manufacturing equipment, components of the process chamber, or the like that results in a pressure differential causing flow of particles toward a substrate (e.g., toward a substrate support pedestal of the process chamber). Operations may include operations that adjust gas flow in a process chamber. Operations may include operations intended to adjust pressure of one or more regions of a process tool, e.g., responsive to a target pressure set point. Operations may include adjustment of an opening of a valve, adjustment of an operation of a flow control valve, adjustment of a pumping speed of a pump system, or the like.

In some systems, one or more adjustments, particularly quick adjustments such as quickly closing a valve, may cause transient pressure gradients in a process chamber. For example, a process recipe may cause a valve coupling the process chamber to an exhaust system to partially or fully close. This may cause a temporary pressure gradient in the chamber, with higher pressures near the exhaust system causing gas backflow toward a substrate processing region of the process chamber. One or more particles may become entrained in gas flowing toward the substrate (e.g., flowing in the gas backflow). The particles may be deposited forming substrate defects.

In some systems, particle defect deposition may be mitigated by making one or more adjustments to operations of the processing system. For example, pressure gradients may be reduced by increasing an amount of time spent performing an operation. A valve may be opened more slowly, a flow rate adjusted over a period of time, or the like to reduce a process chamber pressure gradient, to reduce gas backflow, or the like.

In some systems, efforts may be made to reduce process chamber pressure gradients, gas backflow, particle defect deposition, or the like. Increasing an amount of time for pressure-adjusting operations (e.g., by adjusting process parameters, hardware parameters, equipment constants, or the like) may reduce a likelihood of developing particle defects in substrate processing. Increasing an amount of time for operations of a process recipe may have a significant effect on efficiency of substrate processing procedures. For example, in some process recipes, a cyclic process may include many adjustments to pressure of a process chamber, each lasting a few seconds. Increasing an amount of time to adjust pressure of the chamber by an amount of time on the order of seconds may significantly reduce efficiency of processing substrates, e.g., by increasing total processing time. In some processes, increases of a few seconds to reduce gas backflow may increase processing time by 10%, 20%, 50%, or more.

To protect a substrate from particle defects, while ensuring adequate process efficiency or throughput, a substrate processing operation may be adjusted such that defect formation probability is acceptably low, while efficiency is acceptably high. In some systems, achieving parameters that satisfy these target conditions may be performed by performing a series of experiments. Experiments may include performing process operations on one or more substrates, observing results, and determining whether to adjust one or more parameters. Experiments may be costly in terms of time (e.g., chamber time which is not contributing to usable substrates), technician time, materials, process gases, costs associated with disposing of test substrates, energy costs, environmental impact, etc. Further, adjusting process operations may be done to reduce a likelihood of forming defects, and determining a likelihood of defect formation may include performing series of experiments. Determining an optimal or acceptable set of parameters for reducing backflow while maintaining process efficiency may be a highly costly venture.

Aspects of the present disclosure may address one or more shortcomings of conventional solutions. In some embodiments, a model is generated representative of a process chamber. The model may be representative of gas flow dynamics. The model may be representative of gas pressure. The model may be a physics-based model. The model may be a digital twin model. The model may be a reduced-order model (e.g., based on a physics-based model). The model may be a trained machine learning model. The model may be a computational fluid dynamics model.

The model may be utilized in determining changes to one or more parameters in association with substrate processing operations, pressure adjusting operations, gas flow adjusting operations, or the like. In some embodiments, a target pressure differential, target backflow, target backflow or pressure differential at a location of interest (e.g., proximate a substrate support), or the like may be targeted. Adjustments may be made in modeling the substrate processing system to determine whether a set of parameters satisfies one or more target conditions.

In some embodiments, a first set of parameters (e.g., time to open one or more valves, time to adjust one or more flow rates, or the like) may be modeled. Modeling may determine or predict gas backflow, particle backflow likelihood, particle defect likelihood, gas pressure gradient, or the like. In some embodiments, one or more target conditions may be checked (e.g., is backflow proximate the substrate below a target threshold). Upon determining whether the target conditions are met, further modeling may be performed with a different set of parameters. For example, if it is determined that backflow conditions do not meet a target threshold, one or more hardware operations may be slowed down (e.g., by a fixed value, such as increasing a valve closing time from a nearly instantaneous close to a one second ramp, increasing a one second ramp to a two second ramp, or the like). After determining updated parameters, modeling may be performed again, and conformity of the modeling with the target conditions checked. As another example, if it is determined that backflow conditions do meet a target threshold, one or more hardware operations may be sped up (e.g., reducing a valve closing time by half a second) to check via additional modeling whether an increase of efficiency may be achieved while maintaining target conditions related to reduced likelihood of particle substrate defect formation.

In some embodiments, modeling may be utilized to determine likely sources of particles, particle defects, or the like. In some embodiments, a model (e.g., a physics-based model) may be augmented with particle flow modeling. In some embodiments, particles may be backtracked from a substrate to determine likely particle source locations. In some embodiments, particles may be added to a model from one or more potential source locations, likelihood of travel to the substrate may be determined, and likely sources of particle defects may be predicted based on the modeling.

In some embodiments, operations in association with reducing gas backflow or particle defects may be performed in conjunction with process recipe generation. In some embodiments, particle defect reduction operations may be performed upon determining that particle defect formation exceeds a threshold, e.g., after processing a number of substrates and determining that particle defect formation is unacceptably high. In some embodiments, upon determining that a process recipe includes adjustments to chamber pressure that may result in gas backflow, modeling may be performed to determine whether the process recipe could be adjusted to reduce a likelihood of developing particle defects. In some embodiments, adjustments to process recipes may be performed based on the modeling.

Systems and methods of the present disclosure provide technological advantages over conventional methods. Performing modeling operations to predict process gas backflow may reduce a likelihood of developing particle defects on substrates during processing. Reducing likelihood of defects may increase a likelihood of developing products that meet performance thresholds, increase efficiency of processing in terms of throughput, material cost, energy cost, environmental impact, etc., reduce costs associated with disposing of defective products, reduce wear and tear on substrate processing equipment, etc. Performing modeling operations to predict process gas backflow may improve efficiency of correcting defect root causes compared to other methods. Increased efficiency in correcting root causes may include reduced chamber down time or maintenance time, more time at peak chamber productivity, etc. Performing modeling operations to predict process gas backflow may improve costs of determining defect root causes above experimental methods, by avoiding costs associated with performing experiments to determine a likelihood of defect formation, such as costs associated with process materials, substrate materials, energy expenditure, time, environmental impact, costs associated with disposing of test substrates, etc.

In one aspect of the present disclosure, a method includes providing initial process conditions to a model associated with a process chamber. The method further includes providing an indication of one or more adjustments to the process chamber resulting in final process conditions to the model. The method further includes obtaining an indication of first gas backflow to a substrate support of the process chamber from the model. The method further includes generating updated one or more adjustments to the process chamber. The method further includes providing an indication of the updated one or more adjustments to the model. The method further includes obtaining from the model an indication of second gas backflow to the substrate support. The method further includes performing a corrective action based on the updated one or more adjustments.

In another aspect of the disclosure, a method includes obtaining a plurality of initial process conditions associated with a process chamber. The method further includes obtaining a plurality of process chamber adjustments. The method further includes obtaining a plurality of backflow data, each backflow data associated with one of the initial process conditions and one of the process chamber adjustments. The method further includes training a machine learning model to predict gas backflow by providing the plurality of initial process conditions and plurality of process chamber adjustments as training input, and the plurality of backflow data as target output.

In another aspect of the disclosure, a non-transitory machine-readable storage medium is disclosed. The storage medium stores instructions which, when executed, cause a processing device to perform operations. The operations include providing initial process conditions to a model associated with a process chamber. The operations further include providing an indication of one or more adjustments to the process chamber resulting in final process conditions to the model. The operations further include obtaining an indication of first gas backflow to a substrate support of the process chamber from the model. The operations further include generating updated one or more adjustments to the process chamber. The operations further include providing an indication of the updated one or more adjustments to the model. The operations further include obtaining from the model an indication of second gas backflow to the substrate support. The operations further include performing a corrective action based on the updated one or more adjustments.

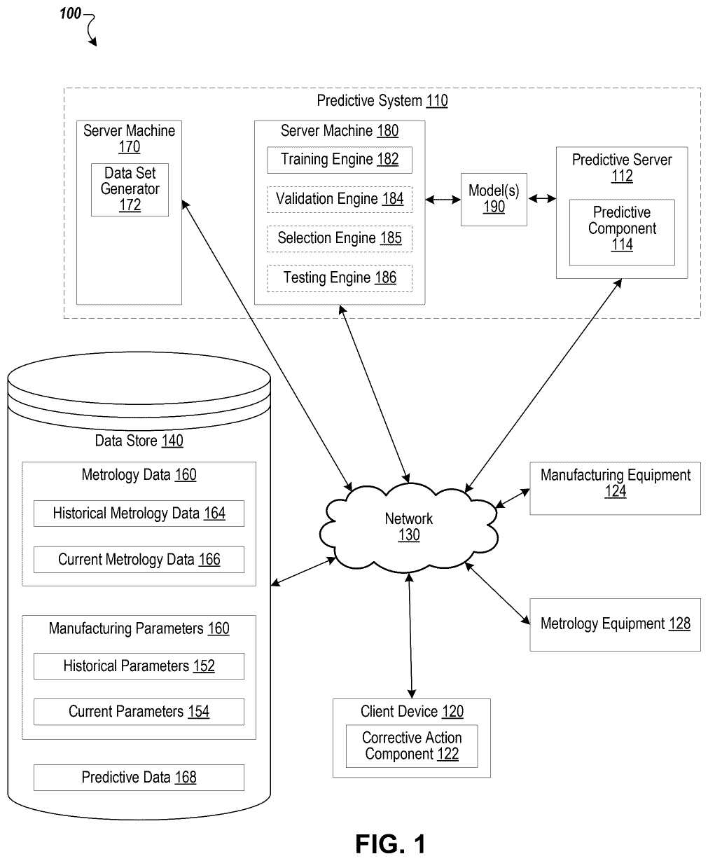

FIG. 1 is a block diagram illustrating an exemplary system 100 (exemplary system architecture), according to some embodiments. The system 100 includes a client device 120, manufacturing equipment 124, metrology equipment 128, predictive server 112, and data store 140. The predictive server 112 may be part of predictive system 110. Predictive system 110 may further include server machines 170 and 180.

Manufacturing equipment 124 may include one or more process tools, process chambers, or the like for performing processing operations to manufacture substrates. Substrates may have property values (film thickness, film strain, etc.) measured by metrology equipment 128. Metrology data 160 may be a component of data store 140. Metrology data 160 may include historical metrology data (e.g., metrology data associated with previously processed products). In some embodiments, historical metrology data may be used in training a machine leaning model, in calibrating a physics-based model, in generating a reduced-order model, or the like. Historical metrology data may be utilized in determining a historical likelihood of developing substrate defects, and the historical likelihood may be utilized in generating a machine learning model, in calibrating a physics-based model, in determining whether to use a model in association with a process of interest, or the like.

Metrology data 160 may be provided by instruments separate from a manufacturing mainframe, e.g., substrates may be measured at a standalone metrology facility. In some embodiments, metrology data 160 may be provided without use of a standalone metrology facility, e.g., in-situ metrology data (e.g., metrology or a proxy for metrology collected during processing), integrated metrology data (e.g., metrology or a proxy for metrology collected while a product is within a chamber or under vacuum, but not during processing operations), inline metrology data (e.g., data collected after a substrate is removed from vacuum), etc. Metrology data 160 may include current metrology data (e.g., metrology data associated with a product currently or recently processed). Current metrology data may be provided to update one or more models in association with defect root cause correction, e.g., by updating weights or biases of a machine learning model, updating parameters of a physics-based model, updating coefficients of a reduced order model, or the like

Data store 140 may further include manufacturing parameters 150. Manufacturing parameters 150 may include parameters associated with performing substrate processing procedures, such as recipe data (e.g., process parameters), equipment constants (e.g., hardware parameters, parameters determining how operations of manufacturing equipment 124 are performed), indications of installed hardware components, or the like. Manufacturing parameter data, similar to metrology data 160, may include historical parameters 152 and current parameters 154. Historical parameters 152 may be utilized in generating a model (e.g., one or more models 190) for defect correction, e.g., to be used to reduce a likelihood of developing a particle defect during substrate processing. Current parameters 154 may be utilized in determining whether a process of interest is likely to generate substrate defects, e.g., by providing the current parameters 154 to model 190.

In some embodiments metrology data 160 and/or manufacturing parameters 150 may be processed (e.g., by the client device 120 and/or by the predictive server 112). Processing of the data may include generating features. In some embodiments, the features are a pattern in the metrology data 160 and/or manufacturing parameters 150 (e.g., slope, width, height, peak, etc.) or a combination of values from the metrology data and/or manufacturing parameters (e.g., power derived from voltage and current, etc.). Manufacturing parameters 160 may include features and the features may be used by predictive component 114 for performing signal processing and/or for obtaining predictive data 168 for performance of a corrective action.

Each instance of metrology data 160 and/or manufacturing parameters 150 may correspond to a product, a set of manufacturing equipment, a type of substrate produced by manufacturing equipment, or the like. A model 190 may also be associated with a particular product, substrate design, set of manufacturing equipment, design of manufacturing chamber, or the like. For example, a fluid dynamics model may be generated based on geometry of a type or design of process tool, a reduced order or machine learning model may be generated based on data from a particular design of chamber or a specific specimen of process chamber (e.g., to account for differences between nominally identical chambers), or the like. The data store may further store information associating sets of different data types, e.g. information indicative that a set of sensor data, a set of metrology data, and a set of manufacturing parameters are all associated with the same product, manufacturing equipment, type of substrate, etc.

In some embodiments, a processing device (e.g., via a model) may be used to generate predictive data 168. Predictive data 168 may include one or more indications of predicted improvements to a processing operation (e.g., to improve efficiency, to reduce gas backflow, to reduce a likelihood of generating particle defects on substrate, or the like). Predictive data 168 may be utilized by system 100 for performance of a corrective action (e.g., providing alerts to a user, updating process recipes, updating manufacturing parameters, scheduling maintenance, or the like).

In some embodiments, predictive system 110 may generate predictive data 168 utilizing a physics-based model. A physics-based model may include a mathematical representation of the laws of nature at play in the process chamber. The physics-based model may be a first principles model, an approximate model, or the like. The physics-based model may include a representation or parameterization of chamber geometry, pumping parameters, gas flow parameters, or the like. The physics-based model may be a gas flow model, a computational fluid dynamics model, a gas pressure model, or the like. A physics-based model may include one or more parameters that are allowed to be adjusted to fit the physics-based model to data, e.g., historical metrology data 164, e.g., to account for details of physics of the process chamber not captured by the original model parameters.

In some embodiments, predictive system 110 may generate predictive data 168 utilizing a reduced order model. A reduced order model may include a simplified version of a complex model (e.g., a simplified version of a computational fluid dynamics model). The reduced order model may mimic the performance of the full model under a target range of conditions (e.g., relevant to substrate processing conditions), while being more computationally efficient. Training data (e.g., historical metrology data 164, historical parameters 152, etc.) may be utilizing in determining which simplifications from a more complete model to make, in determining coefficients of a reduced order model, or the like.

In some embodiments, predictive system 110 may generate predictive data 168 using supervised machine learning (e.g., predictive data 168 includes output from a machine learning model that was trained using labeled data, such as manufacturing parameter data labelled with metrology data (e.g., which may include rates of defect formation, or other metrology of interest). In some embodiments, predictive system 110 may generate predictive data 168 using unsupervised machine learning (e.g., predictive data 168 includes output from a machine learning model that was trained using unlabeled data, output may include clustering results, principle component analysis, anomaly detection, etc.). In some embodiments, predictive system 110 may generate predictive data 168 using semi-supervised learning (e.g., training data may include a mix of labeled and unlabeled data, etc.).

Client device 120, manufacturing equipment 124, metrology equipment 128, predictive server 112, data store 140, server machine 170, and server machine 180 may be coupled to each other via network 130 for generating predictive data 168 to perform corrective actions. In some embodiments, network 130 may provide access to cloud-based services. Operations performed by client device 120, predictive system 110, data store 140, etc., may be performed by virtual cloud-based devices.

In some embodiments, network 130 is a public network that provides client device 120 with access to the predictive server 112, data store 140, and other publicly available computing devices. In some embodiments, network 130 is a private network that provides client device 120 access to manufacturing equipment 124, metrology equipment 128, data store 140, and other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

Client device 120 may include computing devices such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. Client device 120 may include a corrective action component 122. Corrective action component 122 may receive user input (e.g., via a Graphical User Interface (GUI) displayed via the client device 120) of an indication associated with manufacturing equipment 124. In some embodiments, corrective action component 122 transmits the indication to the predictive system 110, receives output (e.g., predictive data 168) from the predictive system 110, determines a corrective action based on the output, and causes the corrective action to be implemented. In some embodiments, corrective action component 122 obtains model input data associated with manufacturing equipment 124 (e.g., from data store 140, etc.) and provides the model input data (e.g., current parameters 154) associated with the manufacturing equipment 124 to predictive system 110.

In some embodiments, corrective action component 122 receives an indication of a corrective action from the predictive system 110 and causes the corrective action to be implemented. Each client device 120 may include an operating system that allows users to one or more of generate, view, or edit data (e.g., indication associated with manufacturing equipment 124, corrective actions associated with manufacturing equipment 124, etc.).

In some embodiments, metrology data 160 (e.g., historical metrology data 164) corresponds to historical property data of products (e.g., products processed using manufacturing parameters associated with historical manufacturing parameters 152) and predictive data 168 is associated with predicted property data (e.g., of products to be produced or that have been produced in conditions recorded by current manufacturing parameters 154). In some embodiments, predictive data 168 is or includes predicted metrology data (e.g., virtual metrology data, particle defect generation likelihood) of the products to be produced or that have been produced according to conditions recorded as current measurement data and/or current manufacturing parameters. In some embodiments, predictive data 168 is or includes predictions of conditions in a process chamber in connection with current parameters 154, such as backflow conditions, pressure gradient conditions, or the like generated in the process chamber. In some embodiments, predictive data 168 is associated with a predicted source of particle defects, e.g., whether defects are predicted to originate from process byproducts, from a chamber wall or other component, from a region beyond an exhaust valve (such as another chamber sharing at least a portion of the exhaust system of the process chamber of interest), or the like. In some embodiments, predictive data 168 is or includes an indication of any abnormalities (e.g., abnormal products, abnormal components, abnormal manufacturing equipment 124, abnormal energy usage, etc.) and optionally one or more causes of the abnormalities. In some embodiments, predictive data 168 is an indication of change over time or drift in some component of manufacturing equipment 124, metrology equipment 128, and the like. In some embodiments, predictive data 168 is an indication of an end of life of a component of manufacturing equipment 124, metrology equipment 128, or the like.

Performing manufacturing processes that result in defective products can be costly in time, energy, products, components, manufacturing equipment 124, the cost of identifying the defects and discarding the defective product, etc. By inputting manufacturing parameters that are being used or are to be used to manufacture a product into predictive system 110, receiving output of predictive data 168, and performing a corrective action based on the predictive data 168, system 100 can have the technical advantage of avoiding the cost of producing, identifying, and discarding defective products.

Performing manufacturing processes that result in failure of the components of the manufacturing equipment 124 can be costly in downtime, damage to products, damage to equipment, express ordering replacement components, etc. By inputting manufacturing parameters that are being used or are to be used to manufacture a product, metrology data, measurement data, etc., receiving output of predictive data 168, and performing corrective action (e.g., predicted operational maintenance, such as replacement, processing, cleaning, etc. of components causing particles to be deposited on substrates during processing) based on the predictive data 168, system 100 can have the technical advantage of avoiding the cost of one or more of unexpected component failure, unscheduled downtime, productivity loss, unexpected equipment failure, product scrap, or the like. Monitoring the performance over time of components, e.g. manufacturing equipment 124, metrology equipment 128, and the like, may provide indications of degrading components.

Manufacturing parameters may be suboptimal for producing product which may have costly results of increased resource (e.g., energy, coolant, gases, etc.) consumption, increased amount of time to produce the products, increased component failure, increased amounts of defective products, etc. By inputting indications of manufacturing parameters 160 into a model 190, receiving an output of predictive data 168, and performing a corrective action of updating manufacturing parameters (e.g., setting optimal manufacturing parameters, updating a process recipe, or the like), system 100 can have the technical advantage of using optimal manufacturing parameters (e.g., hardware parameters, process parameters, optimal design) to avoid costly results of suboptimal manufacturing parameters, including reducing a likelihood of developing particle defects on substrates, maintaining high product throughput while managing a likelihood of developing defects, or the like.

In some embodiments, the corrective action includes providing an alert (e.g., an alarm to stop or not perform the manufacturing process if the predictive data 168 indicates a predicted abnormality, such as an abnormality of the product, a component, or manufacturing equipment 124). In some embodiments, performance of the corrective action includes causing updates to one or more manufacturing parameters. In some embodiments, performance of a corrective action may include recalibration or adjustment of parameters of a physics-based model or reduced order model. In some embodiments performance of a corrective action may include retraining a machine learning model associated with manufacturing equipment 124. In some embodiments, performance of a corrective action may include training a new machine learning model associated with manufacturing equipment 124.

Manufacturing parameters 150 may include hardware parameters (e.g., information indicative of which components are installed in manufacturing equipment 124, indicative of component replacements, indicative of component age, indicative of software version or updates, etc.) and/or process parameters (e.g., temperature, pressure, flow, rate, electrical current, voltage, gas flow, lift speed, etc.). In some embodiments, the corrective action includes causing preventative operative maintenance (e.g., replace, process, clean, etc. components of the manufacturing equipment 124). In some embodiments, the corrective action includes causing design optimization (e.g., updating manufacturing parameters, manufacturing processes, manufacturing equipment 124, etc. for an optimized product). In some embodiments, the corrective action includes a updating a recipe (e.g., altering the timing of manufacturing subsystems entering an idle or active mode, altering set points of various property values, etc.). In some embodiments, a corrective action includes updating a duration of one or more processing actions, such as opening or closing a valve, adjusting a flow meter, or the like. A corrective action may include introducing or adjusting a ramp time for actuating a valve, adjusting operation of a component, or the like.

Predictive server 112, server machine 170, and server machine 180 may each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc. Operations of predictive server 112, server machine 170, server machine 180, data store 140, etc., may be performed by a cloud computing service, cloud data storage service, etc.

Predictive server 112 may include a predictive component 114. In some embodiments, the predictive component 114 may receive current manufacturing parameters (e.g., receive from the client device 120, retrieve from the data store 140) and generate output (e.g., predictive data 168) for performing corrective action associated with the manufacturing equipment 124 based on the current data. In some embodiments, predictive data 168 may include one or more predicted defects of a processed product. In some embodiments, predictive data 168 may include a prediction of conditions in-chamber that may result in defect formation, such as gas backflow. In some embodiments, predictive component 114 may use one or more trained machine learning models 190 to determine the output for performing the corrective action based on current data.

Manufacturing equipment 124 may be associated with one or more models, e.g., model 190. In some embodiments, model(s) 190 may be or include physics-based models, reduced order models, machine learning models, etc. Machine learning models associated with manufacturing equipment 124 may perform many tasks, including process control, classification, performance predictions, etc. Model 190 may be trained using data associated with manufacturing equipment 124 or products processed by manufacturing equipment 124, e.g., sensor data, manufacturing parameters 150 (e.g., associated with process control of manufacturing equipment 124), metrology data 160 (e.g., generated by metrology equipment 128), etc.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs).

A recurrent neural network (RNN) is another type of machine learning model. A recurrent neural network model is designed to interpret a series of inputs where inputs are intrinsically related to one another, e.g., time trace data, sequential data, etc. Output of a perceptron of an RNN is fed back into the perceptron as input, to generate the next output.

Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In an image recognition application, for example, the raw input may be a matrix of pixels; the first representational layer may abstract the pixels and encode edges; the second layer may compose and encode arrangements of edges; the third layer may encode higher level shapes (e.g., teeth, lips, gums, etc.); and the fourth layer may recognize a scanning role. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

In some embodiments, predictive component 114 current metrology data 166 and/or current manufacturing parameters 154, performs signal processing to break down the current data into sets of current data, provides the sets of current data as input to a trained model 190, and obtains outputs indicative of predictive data 168 from the trained model 190. In some embodiments, predictive component 114 receives metrology data (e.g., predicted defect formation likelihood) of a substrate and provides the metrology data to trained model 190. Model 190 may be configured to accept data indicative of manufacturing parameters and generate as output defect formation data. In some embodiments, predictive data is indicative of metrology data (e.g., prediction of substrate quality, substate defect likelihood, or the like). In some embodiments, predictive data is indicative of manufacturing equipment health (e.g., an indication of a component or components likely to be contributing to substrate defects).

In some embodiments, the various models discussed in connection with model 190 (e.g., supervised machine learning model, unsupervised machine learning model, etc.) may be combined in one model (e.g., an ensemble model), or may be separate models.

Data store 140 may be a memory (e.g., random access memory), a drive (e.g., a hard drive, a flash drive), a database system, a cloud-accessible memory system, or another type of component or device capable of storing data. Data store 140 may include multiple storage components (e.g., multiple drives or multiple databases) that may span multiple computing devices (e.g., multiple server computers). The data store 140 may store manufacturing parameters 150, metrology data 160, and predictive data 168.

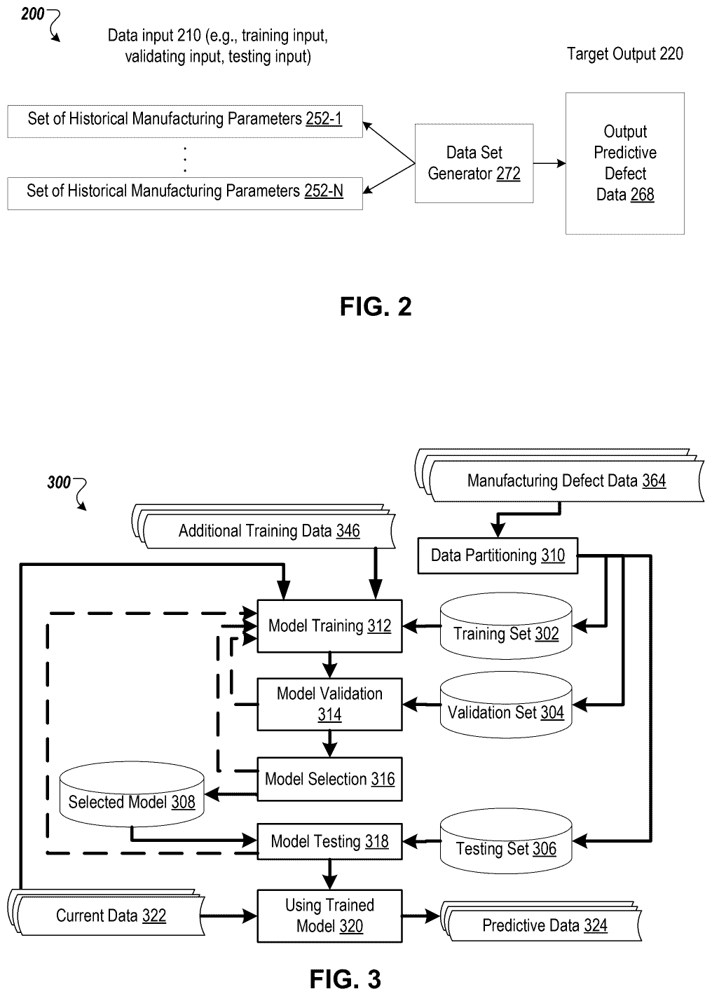

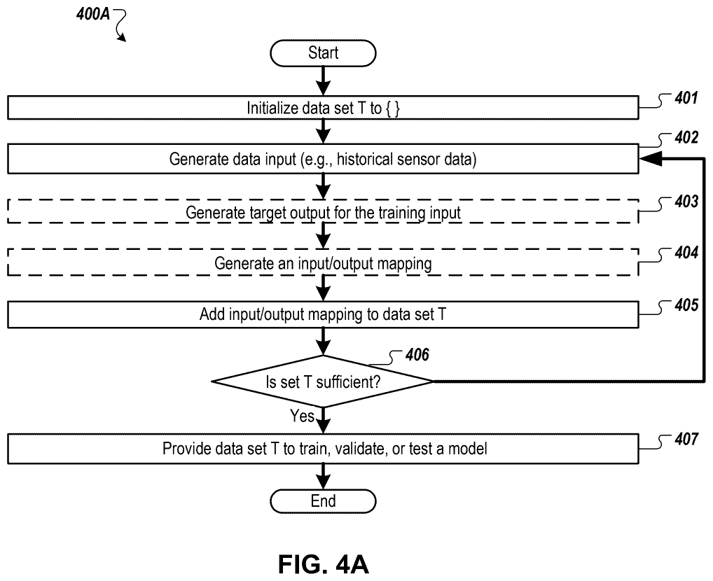

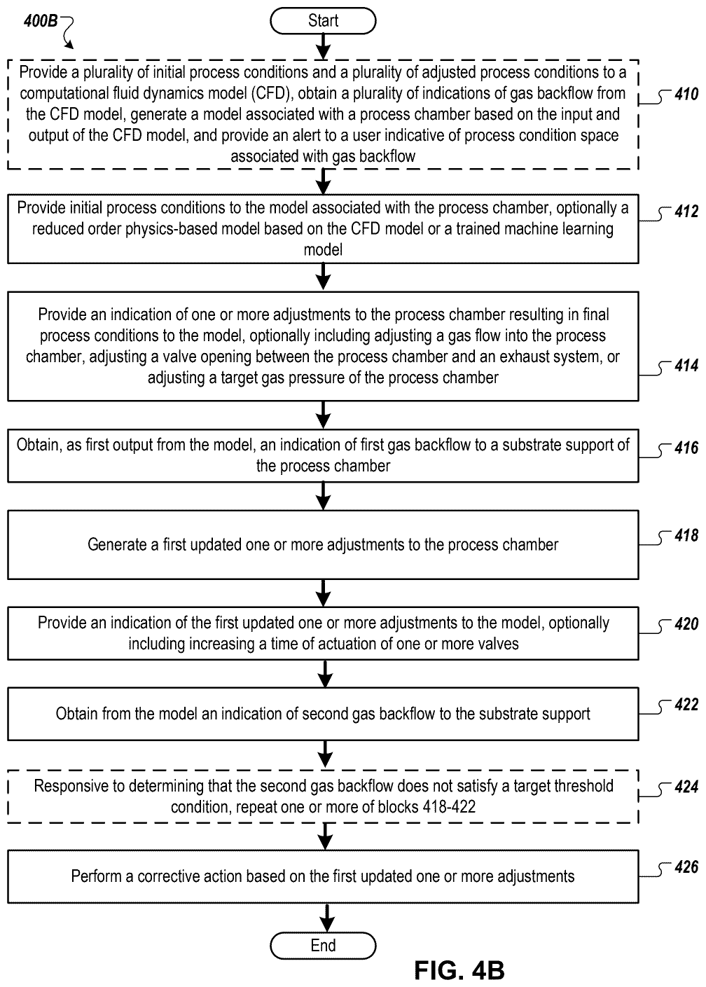

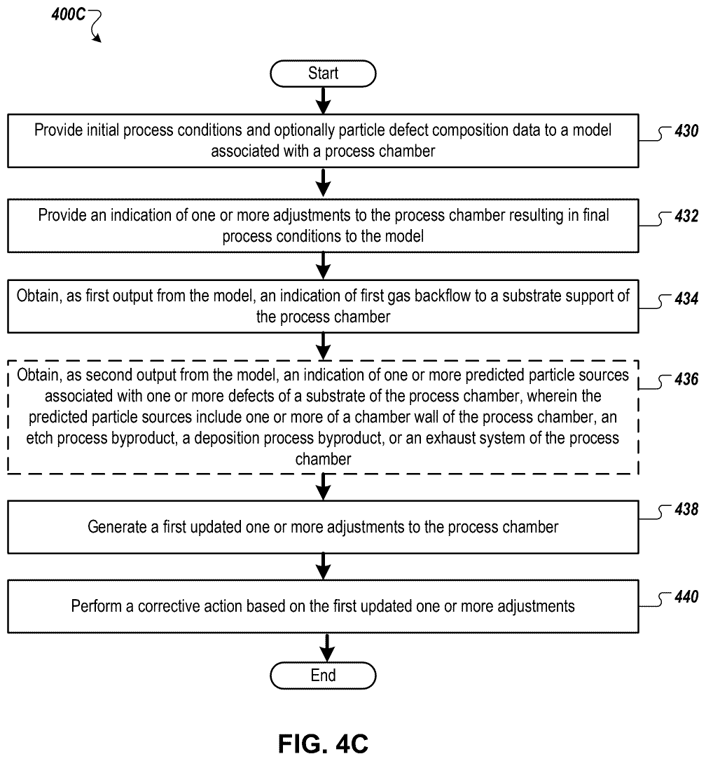

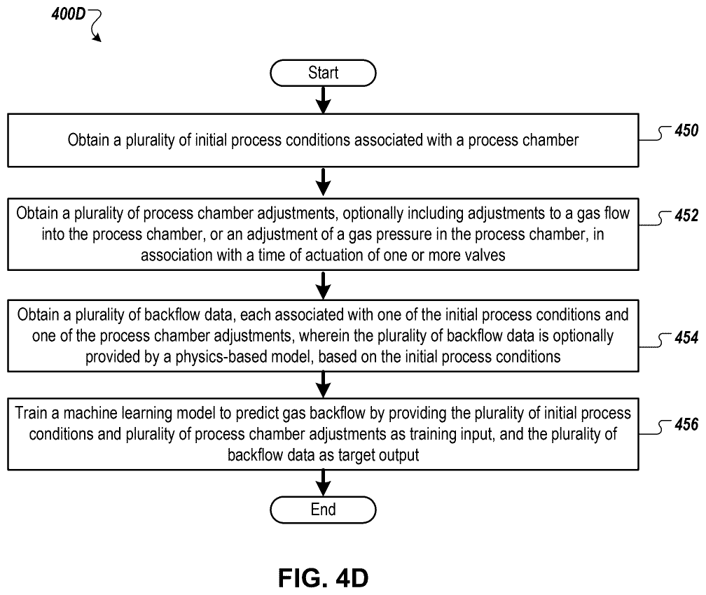

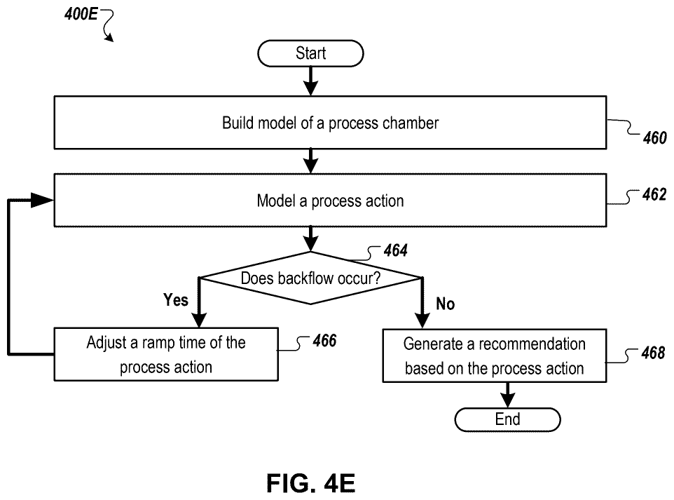

In some embodiments, predictive system 110 further includes server machine 170 and server machine 180. Server machine 170 includes a data set generator 172 that is capable of generating data sets (e.g., a set of data inputs and a set of target outputs) to train, validate, and/or test model(s) 190, including one or more machine learning models. Some operations of data set generator 172 are described in detail below with respect to FIGS. 2 and 4A. In some embodiments, data set generator 172 may partition the historical data (e.g., historical manufacturing parameters 152, historical metrology data 164) into a training set (e.g., sixty percent of the historical data), a validating set (e.g., twenty percent of the historical data), and a testing set (e.g., twenty percent of the historical data).

Server machine 180 includes a training engine 182, a validation engine 184, selection engine 185, and/or a testing engine 186. An engine (e.g., training engine 182, a validation engine 184, selection engine 185, and a testing engine 186) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 may be capable of training a model 190 using one or more sets of features associated with the training set from data set generator 172. The training engine 182 may generate multiple trained models 190, where each trained model 190 corresponds to a distinct set of features of the training set. For example, a first trained model may have been trained using all features (e.g., X1-X5), a second trained model may have been trained using a first subset of the features (e.g., X1, X2, X4), and a third trained model may have been trained using a second subset of the features (e.g., X1, X3, X4, and X5) that may partially overlap the first subset of features. Data set generator 172 may receive the output of a trained, collect that data into training, validation, and testing data sets, and use the data sets to train a second model (e.g., a machine learning model configured to output predictive data, corrective actions, etc.).

Validation engine 184 may be capable of validating a trained model 190 using a corresponding set of features of the validation set from data set generator 172. For example, a first trained machine learning model 190 that was trained using a first set of features of the training set may be validated using the first set of features of the validation set. The validation engine 184 may determine an accuracy of each of the trained models 190 based on the corresponding sets of features of the validation set. Validation engine 184 may discard trained models 190 that have an accuracy that does not meet a threshold accuracy. In some embodiments, selection engine 185 may be capable of selecting one or more trained models 190 that have an accuracy that meets a threshold accuracy. In some embodiments, selection engine 185 may be capable of selecting the trained model 190 that has the highest accuracy of the trained models 190.

Testing engine 186 may be capable of testing a trained model 190 using a corresponding set of features of a testing set from data set generator 172. For example, a first trained machine learning model 190 that was trained using a first set of features of the training set may be tested using the first set of features of the testing set. Testing engine 186 may determine a trained model 190 that has the highest accuracy of all of the trained models based on the testing sets.

In the case of a machine learning model, model 190 may refer to the model artifact that is created by training engine 182 using a training set that includes data inputs and corresponding target outputs (correct answers for respective training inputs. Patterns in the data sets can be found that map the data input to the target output (the correct answer), and machine learning model 190 is provided mappings that capture these patterns. The machine learning model 190 may use one or more of Support Vector Machine (SVM), Radial Basis Function (RBF), clustering, supervised machine learning, semi-supervised machine learning, unsupervised machine learning, k-Nearest Neighbor algorithm (k-NN), linear regression, random forest, neural network (e.g., artificial neural network, recurrent neural network), etc. In some embodiments, one or more machine learning models 190 may be trained using historical data (e.g., historical parameters 152).

Predictive component 114 may provide current data to model 190 and may run model 190 on the input to obtain one or more outputs. For example, predictive component 114 may provide current parameters 154 to model 190 and may run model 190 on the input to obtain one or more outputs. Predictive component 114 may be capable of determining (e.g., extracting) predictive data 168 from the output of model 190. Predictive component 114 may determine (e.g., extract) confidence data from the output that indicates a level of confidence that predictive data 168 is an accurate predictor of a process associated with the input data for products produced or to be produced using the manufacturing equipment 124 at the current manufacturing parameters. Predictive component 114 or corrective action component 122 may use the confidence data to decide whether to cause a corrective action associated with the manufacturing equipment 124 based on predictive data 168.

The confidence data may include or indicate a level of confidence that the predictive data 168 is an accurate prediction for products or components associated with at least a portion of the input data. In one example, the level of confidence is a real number between 0 and 1 inclusive, where 0 indicates no confidence that the predictive data 168 is an accurate prediction for products processed according to input data or component health of components of manufacturing equipment 124 and 1 indicates absolute confidence that the predictive data 168 accurately predicts properties of products processed according to input data or component health of components of manufacturing equipment 124. Responsive to the confidence data indicating a level of confidence below a threshold level for a predetermined number of instances (e.g., percentage of instances, frequency of instances, total number of instances, etc.) predictive component 114 may cause trained model 190 to be re-trained (e.g., based on current manufacturing parameters, current metrology, measurements of conditions in the chamber, etc.). In some embodiments, retraining may include generating one or more data sets (e.g., via data set generator 172) utilizing historical data.

For purpose of illustration, rather than limitation, aspects of the disclosure describe the training of one or more machine learning models 190 using historical data (e.g., historical metrology data 164, historical manufacturing parameters) and inputting current data (e.g., current manufacturing parameters, and current metrology data) into the one or more trained machine learning models to determine predictive data 168. In other embodiments, a heuristic model, physics-based model, or rule-based model is used to determine predictive data 168 (e.g., without using a trained machine learning model). In some embodiments, such models may be trained using historical data. In some embodiments, these models may be retrained utilizing a historical data and/or current data. Predictive component 114 may monitor historical manufacturing parameters, and metrology data 160. Any of the information described with respect to data inputs 210 of FIG. 2 may be monitored or otherwise used in the heuristic, physics-based, or rule-based model.

In some embodiments, the functions of client device 120, predictive server 112, server machine 170, and server machine 180 may be provided by a fewer number of machines. For example, in some embodiments server machines 170 and 180 may be integrated into a single machine, while in some other embodiments, server machine 170, server machine 180, and predictive server 112 may be integrated into a single machine. In some embodiments, client device 120 and predictive server 112 may be integrated into a single machine. In some embodiments, functions of client device 120, predictive server 112, server machine 170, server machine 180, and data store 140 may be performed by a cloud-based service.

In general, functions described in one embodiment as being performed by client device 120, predictive server 112, server machine 170, and server machine 180 can also be performed on predictive server 112 in other embodiments, if appropriate. In addition, the functionality attributed to a particular component can be performed by different or multiple components operating together. For example, in some embodiments, the predictive server 112 may determine the corrective action based on the predictive data 168. In another example, client device 120 may determine the predictive data 168 based on output from the trained machine learning model.

In addition, the functions of a particular component can be performed by different or multiple components operating together. One or more of the predictive server 112, server machine 170, or server machine 180 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

FIG. 2 depicts a block diagram of example data set generator 272 (e.g., data set generator 172 of FIG. 1) to create data sets for training, testing, validating, calibrating, etc. a model (e.g., model 190 of FIG. 1), according to some embodiments. Each data set generator 272 may be part of server machine 170 of FIG. 1. In some embodiments, data set generator 272 may generate data sets to be utilized to adjust, validate, test, or the like a physics-based model or reduced order model. In some embodiments, data set generator 272 may generate data sets to be utilized in generating, validating, etc., machine learning models in association with the manufacturing equipment. In some embodiments, several models associated with manufacturing equipment 124 may be trained, used, and maintained (e.g., within a manufacturing facility). One or more physics-based models, one or more reduced order models, and/or one or more trained machine learning models may be generated and maintained in association with the manufacturing equipment. Each model may be associated with one data set generators 272, multiple models may share a data set generator 272, etc.

FIG. 2 depicts a system 200 including data set generator 272 for creating data sets for one or more supervised models (e.g., including data associated with input to a model and output from the model). Data set generator 272 may create data sets (e.g., data input 210, target output 220) using historical data, which may include manufacturing parameters, defect generation likelihood, gas backflow, fluid dynamic measurements, or the like. In some embodiments, a data set generator similar to data set generator 272 may be utilized to train an unsupervised model, e.g., target output 220 may not be generated by data set generator 272.

Data set generator 272 may generate data sets to train, test, and validate a model, e.g., a machine learning model. Data set generator 272 may generate data sets to calibrate a model, e.g., a physics-based model (including reduced order models). In some embodiments, data set generator 272 may generate data sets for a machine learning model. In some embodiments, data set generator 272 may generate data sets for training, testing, and/or validating a model configured to predict defect generation data in a substrate processing system, such as generating data indicating a likelihood of particle defect formation, a predicted particle source, a recommended update to substrate processing, or the like.

A model to be generated (e.g., trained, calibrated, or the like) may be provided with a set of historical manufacturing parameters 252-1 as data input 210. The set of historical manufacturing parameters 252-1 may include process control set points. The set of historical manufacturing parameters 252-1 may include parameters determining actions of manufacturing equipment, such as ramp times for valve actuation. The model may be configured to accept indications of manufacturing parameters (e.g., current manufacturing parameters) as input and generate predictions related to particle defect generation as output.

Data set generator 272 may be used to generate data sets for any type of model used in association with predicting or correcting particle defect generation. Data set generator 272 may be used to generate data for any type of machine learning model that takes as input historical manufacturing parameter data. Data set generator 272 may be used to generate data for a machine learning model that generates predicted defect generation data, such as predicted conditions leading to particle deposition (e.g., gas backflow data, gas pressure data, etc.), predicted particle sources, predicted updates to manufacturing parameters to prevent defect formation, or the like. Data set generator 272 may be used to generate data for a machine learning model configured to provide process update instructions, e.g., configured to update manufacturing parameters, manufacturing recipes, equipment constants, or the like. Data set generator 272 may be used to generate data for a machine learning model configured to identify a product anomaly and/or processing equipment fault.

In some embodiments, data set generator 272 generates a data set (e.g., training set, validating set, testing set) that includes one or more data inputs 210 (e.g., training input, validating input, testing input). Data inputs 210 may be provided to training engine 182, validating engine 184, or testing engine 186. The data set may be used to train, validate, or test the model (e.g., model 190 of FIG. 1).

In some embodiments, data input 210 may include one or more sets of data. As an example, system 200 may produce sets of manufacturing parameter data that may include one or more of parameter data from one or more types of components, combinations of parameter data from one or more types of components, patterns from parameter data from one or more types of components, or the like. In some embodiments, target output 220 may include sets of output related to the various sets of data input 210.

In some embodiments, data set generator 272 may generate a first data input corresponding to a first set of manufacturing parameters 252-1 to train, validate, or test a first machine learning model. Data set generator 272 may generate a second data input corresponding to a second set of historical manufacturing parameter data (e.g., a set of historical metrology data 252-2, not shown) to train, validate, or test a second machine learning model. Further sets of historical data may further be utilized in generating further machine learning models. Any number of sets of historical data may be utilized in generating any number of machine learning models, up to a final set, set of historical manufacturing parameters 252-N (N representing any target quantity of data sets, models, etc.)

In some embodiments, data set generator 272 may generate a first data input corresponding to a first set of historical manufacturing parameters 252-1 to train, validate, or test a first machine learning model. Data set generator 272 may generate a second data input corresponding to a second set of historical manufacturing parameters 252-2 (not shown) to train, validate, or test a second machine learning model.

In some embodiments, data set generator 272 generates a data set (e.g., training set, validating set, testing set) that includes one or more data inputs 210 (e.g., training input, validating input, testing input) and may include one or more target outputs 220 that correspond to the data inputs 210. The data set may also include mapping data that maps the data inputs 210 to the target outputs 220. In some embodiments, data set generator 272 may generate data for training a model configured to output relevant to preventing particle defect formation, by generating data sets including output predictive defect data 268. Data inputs 210 may also be referred to as “features,” “attributes,” or “information.” In some embodiments, data set generator 272 may provide the data set to training engine 182, validating engine 184, or testing engine 186, where the data set is used to train, validate, or test the model (e.g., one of the machine learning models that are included in model 190, ensemble model 190, etc.).

In some embodiments, subsequent to generating a data set and training, validating, or testing a machine learning model using the data set, the model may be further trained, validated, or tested, or adjusted (e.g., adjusting weights or parameters associated with input data of the model, such as connection weights in a neural network).

FIG. 3 is a block diagram illustrating system 300 for generating output data (e.g., predictive data 168 of FIG. 1), according to some embodiments. In some embodiments, system 300 may be used in conjunction with a model (e.g., physics-based, reduced order, data-based, machine learning, or the like) configured to generate predictive data related to particle defect generation. In some embodiments, system 300 is utilized for generating output data by a model such as model 190 of FIG. 1. In some embodiments, system 300 may be used in conjunction with a model to determine a corrective action associated with manufacturing equipment. In some embodiments, system 300 may be used in conjunction with a model to determine a fault of manufacturing equipment, e.g., a component resulting in particles being deposited on substrates during processing operations. In some embodiments, system 300 may be used in conjunction with a machine learning model to cluster or classify substrates or substrate defects. System 300 may be used in conjunction with a machine learning model with a different function than those listed, associated with a manufacturing system.

At block 310, system 300 (e.g., components of predictive system 110 of FIG. 1) performs data partitioning (e.g., via data set generator 172 of server machine 170 of FIG. 1) of data to be used in training, validating, and/or testing a model, such as a machine learning model. In some embodiments, manufacturing defect data 364 includes historical data, such as historical metrology data (e.g., particle defect generation rates), historical manufacturing parameter data, historical classification data (e.g., classification of whether defects are likely deposited particles), measured chamber condition data (e.g., indicative of backflow), etc. In some embodiments, e.g., when utilizing physics-based model data to train a machine learning model, manufacturing defect data 364 may include data output by a physics-based model (e.g., a computationally expensive computational fluid dynamics model). Manufacturing defect data 364 may undergo data partitioning at block 310 to generate training set 302, validation set 304, and testing set 306. For example, the training set may be 60% of the training data, the validation set may be 20% of the training data, and the testing set may be 20% of the training data.

The generation of training set 302, validation set 304, and testing set 306 may be tailored for a particular application. For example, the training set may be 60% of the training data, the validation set may be 20% of the training data, and the testing set may be 20% of the training data. System 300 may generate a plurality of sets of features for each of the training set, the validation set, and the testing set. For example, if manufacturing defect data 364 includes manufacturing parameters, including features derived from 20 recipe parameters and 10 hardware parameters, the data may be divided into a first set of features including recipe parameters 1-10 and a second set of features including recipe parameters 11-20. The hardware parameters may also be divided into sets, for instance a first set of hardware parameters including parameters 1-5, and a second set of hardware parameters including parameters 6-10. Either target input, target output, both, or neither may be divided into sets. Multiple models may be trained on different sets of data.

At block 312, system 300 performs model training (e.g., via training engine 182 of FIG. 1) using training set 302. Training of a machine learning model and/or of a physics-based model (e.g., a digital twin) may be achieved in a supervised learning manner, which involves providing a training dataset including labeled inputs through the model, observing its outputs, defining an error (by measuring the difference between the outputs and the label values), and using techniques such as deep gradient descent and backpropagation to tune the weights of the model such that the error is minimized. In many applications, repeating this process across the many labeled inputs in the training dataset yields a model that can produce correct output when presented with inputs that are different than the ones present in the training dataset. In some embodiments, training of a machine learning model may be achieved in an unsupervised manner, e.g., labels or classifications may not be supplied during training. An unsupervised model may be configured to perform anomaly detection, result clustering, etc.

For each training data item in the training dataset, the training data item may be input into the model (e.g., into the machine learning model). The model may then process the input training data item (e.g., one or more manufacturing parameter values, etc.) to generate an output. The output may include, for example, a likelihood of defect formation or an indication of chamber conditions related to defect formation, such as gas backflow. The output may be compared to a label of the training data item (e.g., a measured defect likelihood or measured/modeled gas backflow).

Processing logic may then compare the generated output (e.g., predicted defect generation data) to the label (e.g., actual defect generation data) that was included in the training data item. Processing logic determines an error (i.e., a classification error) based on the differences between the output and the label(s). Processing logic adjusts one or more weights and/or values of the model based on the error.

In the case of training a neural network, an error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

System 300 may train multiple models using multiple sets of features of the training set 302 (e.g., a first set of features of the training set 302, a second set of features of the training set 302, etc.). For example, system 300 may train a model to generate a first trained model using the first set of features in the training set (e.g., manufacturing parameter data from components 1-10, condition predictions 1-10, etc.) and to generate a second trained model using the second set of features in the training set (e.g., manufacturing parameter data from components 11-20, modeling process chamber conditions 11-20, etc.). In some embodiments, the first trained model and the second trained model may be combined to generate a third trained model (e.g., which may be a better predictor than the first or the second trained model on its own). In some embodiments, sets of features used in comparing models may overlap (e.g., first set of features being parameters 1-15 and second set of features being parameters 5-20). In some embodiments, hundreds of models may be generated including models with various permutations of features and combinations of models.

At block 314, system 300 performs model validation (e.g., via validation engine 184 of FIG. 1) using the validation set 304. The system 300 may validate each of the trained models using a corresponding set of features of the validation set 304. For example, system 300 may validate the first trained model using the first set of features in the validation set (e.g., parameters 1-10 or conditions 1-10) and the second trained model using the second set of features in the validation set (e.g., parameters 11-20 or conditions 11-20). In some embodiments, system 300 may validate hundreds of models (e.g., models with various permutations of features, combinations of models, etc.) generated at block 312. At block 314, system 300 may determine an accuracy of each of the one or more trained models (e.g., via model validation) and may determine whether one or more of the trained models has an accuracy that meets a threshold accuracy. Responsive to determining that none of the trained models has an accuracy that meets a threshold accuracy, flow returns to block 312 where the system 300 performs model training using different sets of features of the training set. Responsive to determining that one or more of the trained models has an accuracy that meets a threshold accuracy, flow continues to block 316. System 300 may discard the trained models that have an accuracy that is below the threshold accuracy (e.g., based on the validation set).

At block 316, system 300 performs model selection (e.g., via selection engine 185 of FIG. 1) to determine which of the one or more trained models that meet the threshold accuracy has the highest accuracy (e.g., the selected model 308, based on the validating of block 314). Responsive to determining that two or more of the trained models that meet the threshold accuracy have the same accuracy, flow may return to block 312 where the system 300 performs model training using further refined training sets corresponding to further refined sets of features for determining a trained model that has the highest accuracy.

At block 318, system 300 performs model testing (e.g., via testing engine 186 of FIG. 1) using testing set 306 to test selected model 308. System 300 may test, using the first set of features in the testing set (e.g., parameters 1-10), the first trained model to determine the first trained model meets a threshold accuracy. Determining whether the first trained model meets a threshold accuracy may be based on the first set of features of testing set 306. Responsive to accuracy of the selected model 308 not meeting the threshold accuracy, flow continues to block 312 where system 300 performs model training (e.g., retraining) using different training sets corresponding to different sets of features. Accuracy of selected model 308 may not meet threshold accuracy if selected model 308 is overly fit to the training set 302 and/or validation set 304. Accuracy of selected model 308 may not meet threshold accuracy if selected model 308 is not applicable to other data sets, including testing set 306. Training using different features may include training using data from different sensors, different manufacturing parameters, etc. Responsive to determining that selected model 308 has an accuracy that meets a threshold accuracy based on testing set 306, flow continues to block 320. In at least block 312, the model may learn patterns in the training data to make predictions. In block 318, the system 300 may apply the model on the remaining data (e.g., testing set 306) to test the predictions.

At block 320, system 300 uses the trained model (e.g., selected model 308) to receive current data 322 and determines (e.g., extracts), from the output of the trained model, predictive data 324. Current data 322 may be manufacturing parameters related to a process, operation, or action of interest. Current data 322 may be manufacturing parameters related to a process under development, redevelopment, investigation, etc. Current data 322 may be manufacturing parameters related to a gas transport system. Current data 322 may be manufacturing parameters that may have an effect on delay of changes to condition values compared to initiation of condition-altering actions. Current data 322 may be manufacturing parameters related to gas delivery and/or gas removal in association with a substrate processing chamber. A corrective action associated with the manufacturing equipment 124 of FIG. 1 may be performed in view of predictive data 324. In some embodiments, current data 322 may correspond to the same types of features in the historical data used to train the machine learning model. In some embodiments, current data 322 corresponds to a subset of the types of features in historical data that are used to train selected model 308. For example, a machine learning model may be trained using a number of manufacturing parameters, and configured to generate output based on a subset of the manufacturing parameters.

In some embodiments, the performance of a machine learning model trained, validated, and tested by system 300 may deteriorate. For example, a manufacturing system associated with the trained machine learning model may undergo a gradual change or a sudden change. A change in the manufacturing system may result in decreased performance of the trained machine learning model. A new model may be generated to replace the machine learning model with decreased performance. The new model may be generated by altering the old model by retraining, by generating a new model, etc.

Generation of a new model may include providing additional training data 346. Generation of a new model may further include providing current data 322, e.g., data that has been used by the model to make predictions. In some embodiments, current data 322 when provided for generation of a new model may be labeled with an indication of an accuracy of predictions generated by the model based on current data 322. Additional training data 346 may be provided to model training 312 for generation of one or more new machine learning models, updating, retraining, and/or refining of selected model 308, etc.

In some embodiments, one or more of the acts 310-320 may occur in various orders and/or with other acts not presented and described herein. In some embodiments, one or more of acts 310-320 may not be performed. For example, in some embodiments, one or more of data partitioning of block 310, model validation of block 314, model selection of block 316, or model testing of block 318 may not be performed.

FIG. 3 depicts a system configured for training, validating, testing, and using one or more machine learning models. The machine learning models are configured to accept data as input (e.g., set points provided to manufacturing equipment, sensor data, metrology data, etc.) and provide data as output (e.g., predictive data, corrective action data, classification data, etc.). Partitioning, training, validating, selection, testing, and using blocks of system 300 may be executed similarly to train a second model, utilizing different types of data. Retraining may also be performed, utilizing current data 322 and/or additional training data 346.

FIGS. 4A-E are flow diagrams of methods 400A-E associated with utilizing models to predict and/or correct substrate particle defect root causes, according to certain embodiments. Methods 400A-E may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, methods 400A-E may be performed, in part, by predictive system 110. Method 400A may be performed, in part, by predictive system 110 (e.g., server machine 170 and data set generator 172 of FIG. 1, data set generator 272 of FIG. 2). Predictive system 110 may use method 400A to generate a data set to at least one of train, validate, or test a model (e.g., a physics-based model, a reduced order model, a machine learning model), in accordance with embodiments of the disclosure. Methods 400B-E may be performed by predictive server 112 (e.g., predictive component 114) and/or server machine 180 (e.g., training, validating, and testing operations may be performed by server machine 180). In some embodiments, a non-transitory machine-readable storage medium stores instructions that when executed by a processing device (e.g., of predictive system 110, of server machine 180, of predictive server 112, etc.) cause the processing device to perform one or more of methods 400A-E.

For simplicity of explanation, methods 400A-E are depicted and described as a series of operations. However, operations in accordance with this disclosure can occur in various orders and/or concurrently and with other operations not presented and described herein. Furthermore, not all illustrated operations may be performed to implement methods 400A-E in accordance with the disclosed subject matter. In addition, those skilled in the art will understand and appreciate that methods 400A-E could alternatively be represented as a series of interrelated states via a state diagram or events.

FIG. 4A is a flow diagram of a method 400A for generating a data set for a model, according to some embodiments. Referring to FIG. 4A, in some embodiments, at block 401 the processing logic implementing method 400A initializes a training set T to an empty set.

At block 402, processing logic generates first data input (e.g., first training input, first validating input) that may include one or more of manufacturing parameters, metrology data, process chamber condition data, etc. In some embodiments, the first data input may include a first set of features for types of data and a second data input may include a second set of features for types of data (e.g., as described with respect to FIG. 3). Input data may include historical data and/or data output by a model (e.g., a physics-based model output used for training a machine learning model).

In some embodiments, at block 403, processing logic optionally generates a first target output for one or more of the data inputs (e.g., first data input). In some embodiments, the input includes one or more manufacturing parameters and the target output is an indication related to particle defect formation. In some embodiments, the target output is a recommended corrective action, such as an update to a ramp time for opening one or more valves in a process operation. In some embodiments, the first target output is predictive data.

At block 404, processing logic optionally generates mapping data that is indicative of an input/output mapping. The input/output mapping (or mapping data) may refer to the data input (e.g., one or more of the data inputs described herein), the target output for the data input, and an association between the data input(s) and the target output. In some embodiments, such as in association with machine learning models where no target output is provided, block 404 may not be executed.

At block 405, processing logic adds the mapping data generated at block 404 to data set T, in some embodiments.

At block 406, processing logic branches based on whether data set Tis sufficient for at least one of training, validating, and/or testing a machine learning model, such as synthetic data generator 174 or model 190 of FIG. 1. If so, execution proceeds to block 407, otherwise, execution continues back at block 402. It should be noted that in some embodiments, the sufficiency of data set T may be determined based simply on the number of inputs, mapped in some embodiments to outputs, in the data set, while in some other embodiments, the sufficiency of data set T may be determined based on one or more other criteria (e.g., a measure of diversity of the data examples, accuracy, etc.) in addition to, or instead of, the number of inputs.

At block 407, processing logic provides data set T (e.g., to server machine 180) to train, validate, and/or test machine learning model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping (e.g., numerical values associated with data inputs 210) are input to the neural network, and output values (e.g., numerical values associated with target outputs 220) of the input/output mapping are stored in the output nodes of the neural network. The connection weights in the neural network are then adjusted in accordance with a learning algorithm (e.g., back propagation, etc.), and the procedure is repeated for the other input/output mappings in data set T. After block 407, a model (e.g., model 190) can be at least one of trained using training engine 182 of server machine 180, validated using validating engine 184 of server machine 180, or tested using testing engine 186 of server machine 180. The trained model may be implemented by predictive component 114 (of predictive server 112) to generate predictive data 168 for performing signal processing, or for performing a corrective action associated with manufacturing equipment 124.

FIG. 4B is a flow diagram of a method 400B for utilizing a model for predicting and/or correcting a particle defect root cause of a substrate processing system, according to some embodiments. At block 410, processing logic optionally provides a plurality of initial process conditions and a plurality of adjusted process conditions to a computational fluid dynamics (CFD) model. In some embodiments, the initial process conditions may include process chamber pressure, process chamber gas flow, or the like. The adjusted process conditions may include a change to gas flow, pressure, or the like. The adjusted process conditions may include a method of adjusting the process conditions, such as actuating one or more valves. The adjusted process conditions may include parameters related to methods of adjusting the process conditions, such as an actuation ramp time of the one or more valves.

Processing logic further obtains a plurality of indications of gas backflow from the CFD model. Based on the input process conditions and process condition adjustments, and the gas backflow output of the CFD model, a model for determining particle defect data is generated in association with the process chamber. The model may be a trained machine learning model, a reduced order model, or the like. Optionally, a user may be provided with an indication of process condition space associated with gas backflow. For example, a plot may be provided with an initial process condition on one axis, a final process condition on the second axis, with a color or other indicator on the plot indicating a parameter in association with the process conditions that enables particle generation, gas backflow, or another condition of interest to satisfy a target condition. For example, a ramp time resulting in acceptably low gas backflow may be indicated for various regions of process condition space.

At block 412, processing logic provides initial process conditions to the model associated with the process chamber. The model may be a CFD model, a full physics-based model, a reduced order model, a trained machine learning model, or the like. The model may be configured to generate indications related to defect formation (e.g., particle deposition, gas backflow, gas pressure gradient, or the like) based on input conditions (e.g., initial process conditions, final process conditions, and an indication of actions taken by the processing system to transition between the initial and final conditions).

At block 414, processing logic provides an indication of one or more adjustments to the process chamber resulting in final process conditions to the model. The adjustments to the process chamber may include adjusting a gas flow into the process chamber, adjusting a valve opening coupling the process chamber to an exhaust system, making other adjustments to increase pressure in the chamber, or the like. The adjustment may optionally include a time of actuation of one or more valves.

At block 416, processing logic obtains, as first output from the model, an indication of first gas backflow to a substrate support of the process chamber. The substrate support may be a location where a substrate is to be located during substrate processing operations. The indication of first gas backflow may include a predicted backflow volume, velocity, or the like in regions likely to deposit a particle on the substrate. The indication of first gas backflow may include an indication of a pressure gradient in the process chamber, e.g., which may cause a particle to be entrained in a flow toward the substrate. The indication of first gas backflow may include a likelihood of generating a particle defect, e.g., based on correlations between parameters and inputs learned during training of a machine learning model.

At block 418, processing logic generates a first updated one or more adjustments to the process chamber. The first one or more updated adjustments may include adjusting a ramp time of actuating a valve. The first one or more updated adjustments may include increasing an amount of time associated with at least partially closing a valve coupling the process chamber to an exhaust system. The first one or more updated adjustments may be based on increasing or decreasing a ramp time by a selected time change, e.g., a process may include increasing a valve opening ramp by an increment until a satisfactory valve opening ramp time is found. For example, a ramp time for some processing action (such as valve actuation) may be adjusted by one second, backflow conditions may be checked based on the adjusted action, and the ramp time may again be adjusted by one second until satisfactory performance is predicted. Ramp time adjustments may be of a fixed value (e.g., any time duration change of interest, any time duration change between 0.1 seconds and 5 seconds, about 1 second, or the like), ramp time adjustments may be based on a distance between current conditions and target conditions (e.g., to correct a small backflow, a smaller ramp duration change may be suggested), or the like.

At block 420, processing logic provides an indication of the first updated one or more adjustments to the model, such as a change to a ramp time for actuation of one or more valves. At block 422, processing logic obtains from the model an indication of second gas backflow to the substrate support. The second gas backflow may be provided by the model based on the updated one or more adjustments.

At block 424, processing logic optionally determines that the second gas backflow does not satisfy a target threshold, responsive to receiving the second gas backflow from the model. Upon determining that the second gas backflow does not satisfy a target threshold, operations may be repeated, e.g., a new updated adjustment may be generated and provided to the model, new backflow data may be received and checked in relation to the target threshold, etc. This process may be repeated until the one or more target thresholds (e.g., sufficiently small gas backflow, sufficiently high processing efficiency, or the like) are satisfied.

At block 426, processing logic performs a corrective action based on the first updated one or more adjustments. The corrective action may include updating a process recipe. The corrective action may include scheduling maintenance. The corrective action may include updating one or more equipment constants. The corrective action may include updating one or more model parameters, such as weights or biases of a trained machine learning model, coefficients of a reduced order model, parameters of a physics-based model, or the like.

FIG. 4C is a flow diagram of a method 400C for correcting one or more substrate defect root causes, according to some embodiments. At block 430, processing logic provides initial process conditions to a model associated with a process chamber. Optionally, particle defect composition data (e.g., generated by metrology operations, generated based on spectral defect data, or the like) may be provided to the model.

At block 432, processing logic provides an indication of one or more adjustments to the process chamber resulting in final process conditions to the model. The adjustments may include actuating one or more valves, adjusting one or more gas flows, or the like.

At block 434, processing logic obtains, as first output from the model, an indication of first gas backflow to a substrate support of the process chamber. Operations of block 434 may share one or more features with operations of block 416 of FIG. 4B.

At block 436, processing logic obtains, a second output from the model, an indication of one or more predicted particle sources. The particle sources may be associated with a substrate of the process chamber, e.g., associated with defects measured on one or more substrates processed by the process chamber. The predicted particle sources may include various locations, components, process operations, or the like which may result in particle defects. The predicted particle source may include a chamber wall, an etch process byproduct, a deposition process byproduct, an exhaust system of the process chamber, or the like. For example, an exhaust system may be shared between multiple process chambers, and particles liberated from another chamber sharing an exhaust system may arrive in the process chamber due to gas backflow conditions. Generating predictions of particle source may include reversing likely particle deposition locations, e.g., back tracking based on gas backflow data to determine a likely origin of one or more particle defects. Generating predictions of particle sources may include augmenting modeling of gas flow conditions by introducing particles into the modeling, e.g., introducing particles in a computational fluid dynamics model close to particle locations of interest, and determining whether particles from locations of interest may be deposited on the substrate.

In some embodiments, determining particle sources may further be based on the particle defect composition data. Particles of a first composition may be more likely to originate from a first potential particle source, particles of a second composition may be more likely to originate form a second potential particle source, etc. Determining a particle source may include modeling particle flow from regions of a chamber associated with the particle composition.

At block 438, processing logic generates a first updated one or more adjustments to the process chamber. Operations of block 438 may share one or more features with operations of block 418 of FIG. 4B.

At block 440, processing logic performs a corrective action based on the first updated one or more adjustments. Operations of block 440 may share one or more features with operations of block 426 of FIG. 4B.

FIG. 4D is a flow diagram of a method 400D for generating a trained machine learning model for performing operations in association with particle defects of a substrate processing system, according to some embodiments. At block 450, processing logic obtains a plurality of initial process conditions associated with a process chamber. The initial process conditions may include pressure in the process chamber. The initial process conditions may include gas flow of one or more gases in the process chamber.

At block 452, processing logic obtains a plurality of process chamber adjustments. The plurality of process chamber adjustments may optionally include adjustments to a gas pressure in the process chamber, adjustment of gas flow into the process chamber, or the like. The adjustment may include a manner of adjustment, one or more operations of the process chamber for enacting the adjustment, or the like. For example, actuation of one or more valves, including a ramp time for actuating the one or more valves, may be included in the manner of adjustment data.

At block 454, processing logic obtains a plurality of backflow data, each associated with one of the initial process conditions (e.g., associated with a set of initial process conditions) and one of the process chamber adjustments (e.g., associated with a set of operations performed by the processing system to enact a target condition change). In some embodiments, the backflow data includes defect data, e.g., a measured or estimated likelihood of developing a defect based on the process conditions. In some embodiments, the backflow data includes output of a model, e.g., output of a physics-based (e.g., computationally expensive model, CFD model, or the like) model may be utilized as training data for a machine learning model.

At block 456, processing logic trains a machine learning model. Training the machine learning model includes providing the plurality of initial process conditions and plurality of process chamber adjustments as training input, and the plurality of backflow data as target output. The machine learning model may be trained to predict gas backflow. The model may be trained to predict defect formation likelihood. The model may be trained to predict defect particle sources. The model may be trained to recommend and/or enact corrective actions.

FIG. 4E is a flow diagram for an example method 400E for using a model to adjust operations of a process chamber, according to some embodiments. At block 460, a model of a process chamber developed. As described previously, the model may be a physics-based model, a data-based model, or the like.

At block 462, a process action is modeling utilizing the model. The process action may be an action intended to adjust pressure in the process chamber. The process action may include actuating one or more valves. The process action may include at least partially closing a valve coupled to an exhaust system. As an example, to adjust a chamber pressure from 50 millitorr to 10 millitorr, a valve leading to an exhaust system may be closed from a 90% opening to a 10% opening. The process action may initially modeled or performed as a step change, e.g., the valve may be actuated effectively instantly (e.g., on the scale of gas dynamics in the process chamber), may be actuated at a high speed, or the like.

At block 464, output of the model is analyzed to determine if backflow occurs. Whether or not backflow occurs may be based on an assessment of whether or not one or more conditions in the process chamber satisfies a threshold condition. For example, the threshold condition may include a target maximum pressure gradient proximate the substrate, a target maximum modeled backflow velocity of gas, or the like.

Flow splits based on whether backflow has been determined to occur. If backflow does occur under the modeled conditions, at block 466 a ramp time of the process action is adjusted. For example, a fixed duration may be added to the process action (e.g., to reduce backflow). In some embodiments, the fixed duration may be about 1 second. In some embodiments (not shown), a method similar to method 400E may be utilized to increase process efficiency, by subtracting time from a process action in response to determining that conditions are acceptable. After adjustments to the ramp time, flow returns to block 462, and modeling is performed based on the adjusted process action. This process may repeat until a ramp time resulting in acceptable performance is achieved.

If backflow is determined to not occur, flow proceeds to block 468. At block 468, a recommendation is generated based on the process action, such as a recommendation to update a process recipe to incorporate the adjusted process action, a recommendation to update one or more equipment constants to achieve the adjusted process action, or the like.

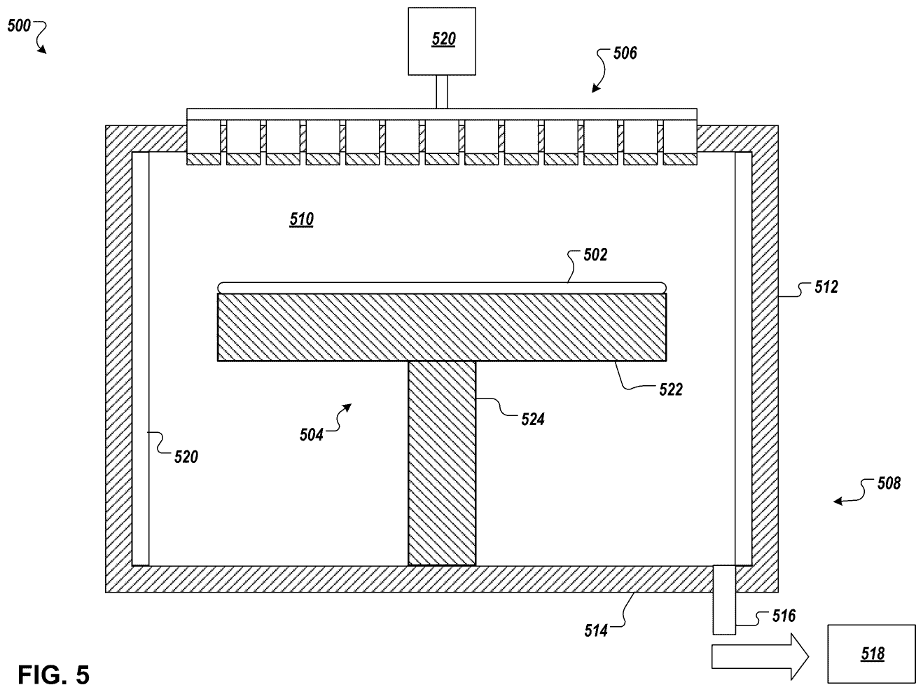

FIG. 5 depicts a sectional view of a processing chamber 500 that may be modeled for determining predictive data in association with particle defects, according to some embodiments. Processing chamber 500 may include one or more components that may contribute to the formation of particle defects on a processed substrate, such as substrate 502. Examples of chamber components that may be a part of processing chamber 500 include a substrate support assembly 504, an electrostatic chuck (ESC), a ring (e.g., a process kit ring or single ring), a chamber wall, a base, a gas distribution plate, a showerhead 506, a nozzle, a lid, a liner, a liner kit, a shield, a plasma screen, a flow equalizer, a cooling base, a chamber viewport, a chamber lid, and so on.

In one embodiment, processing chamber 500 includes a chamber body 508 and a showerhead 506 that enclose an interior volume 510. The showerhead may include a showerhead base and a showerhead gas distribution plate. Alternatively, the showerhead 506 may be replaced by a lid and a nozzle in some embodiments. The chamber body 508 may be fabricated from aluminum, stainless steel, nickel, or other suitable material. The chamber body 508 generally includes sidewalls 512 and a bottom 514. Any of the showerhead 506 (or lid and/or nozzle), sidewalls 512 and/or bottom 514 may include an arcing and/or plasma resistant coating layer. In some embodiments, sides, top, and/or bottom of chamber 500 may include a liner 520.

Particle defects may originate from a number of components of chamber 500. For example, sidewalls 512, bottom 514, and/or liner 520 may liberate particles during substrate processing. Coatings of these components, and/or chemistries of process materials or process byproducts may interact with these or other components to liberate particles. In some embodiments, gases provided via showerhead 506 may generate particles, or in the case of a plasma processing chamber, plasma products or plasma processing byproducts may generate particles that may form substrate defects. Other components, including substrate support assembly 504, pedestal 524, substrate support 522, or the like may contribute to generation of substrate particle defects.

An exhaust port 516 may be defined in the chamber body 508, and may couple the interior volume 510 to a pump system 518. The pump system 518 may include one or more pumps and throttle valves utilized to evacuate and regulate the pressure of the interior volume 510 of processing chamber 500. In some embodiments, one or more particles may be provided to substrate 502 from exhaust port 516, e.g., from backflow from pump system 518, from another chamber coupled to pump system 518, or the like.

A gas panel 520 may be coupled to processing chamber 500 to provide process and/or cleaning gases to the interior volume 510 through showerhead 506 or lid and nozzle. Showerhead 506 is used for processing chambers used for dielectric etch (etching of dielectric materials). The showerhead 506 includes a gas distribution plate (GDP) having multiple gas delivery holes throughout the GDP.

Further components may be sources of particle defects, such as process ring kits, shield, plasma screen, insulator, cooling plate, or other potential particle sources.

A model may be generated based on chamber 500 for determining predictive particle defect data. The model may be a physics-based model, which incorporates geometrical or other flow constraints in association with the design, geometry, and/or construction of chamber 100. The model may be a CFD model. In some embodiments, the model may generate an indication of gas pressure distribution throughout chamber 500, e.g., responsive to some action such as closing a valve coupled to pump system 518. The model may generate an indication of gas backflow responsive to some action such as closing a valve coupled to pump system 518. The model may include particle tracking, e.g., the model may be configured to simulate particle motion of particles proximate one or more components of interest, to determine whether under a set of conditions, particles are likely to be deposited from the components of interest to substrate 502. In some embodiments, data may be used for generation of the model, such as calibrating a CFD model, verifying a simplified reduced order model, training a machine learning model, or the like.

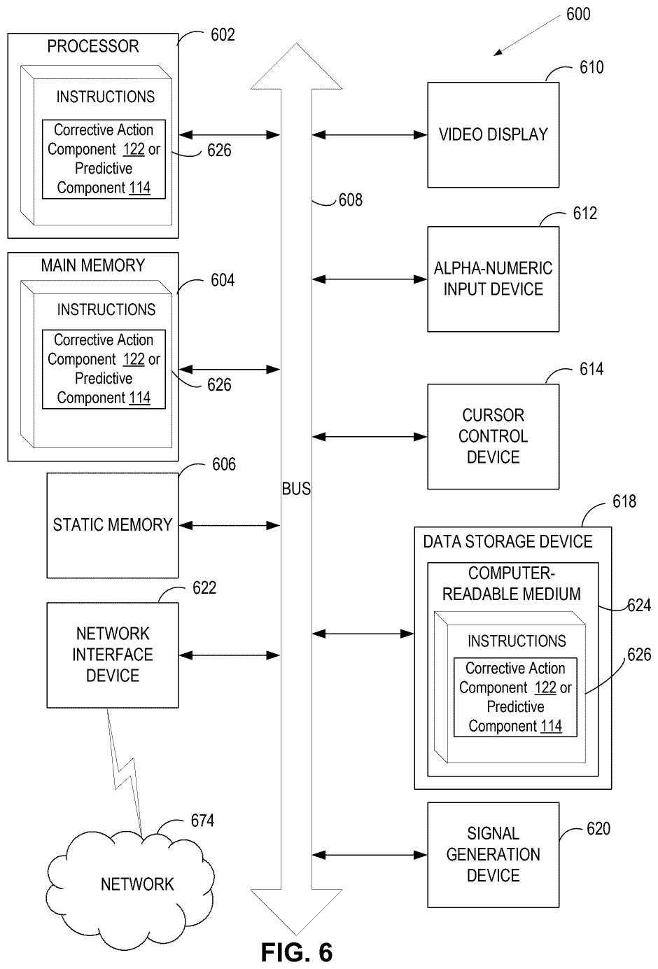

FIG. 6 is a block diagram illustrating a computer system 600, according to some embodiments. In some embodiments, computer system 600 may be connected (e.g., via a network, such as a Local Area Network (LAN), an intranet, an extranet, or the Internet) to other computer systems. Computer system 600 may operate in the capacity of a server or a client computer in a client-server environment, or as a peer computer in a peer-to-peer or distributed network environment. Computer system 600 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 may include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 618, which may communicate with each other via a bus 608.

Processing device 602 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 may further include a network interface device 622 (e.g., coupled to network 674). Computer system 600 also may include a video display unit 610 (e.g., an LCD), an alphanumeric input device 612 (e.g., a keyboard), a cursor control device 614 (e.g., a mouse), and a signal generation device 620.

In some embodiments, data storage device 618 may include a non-transitory computer-readable storage medium 624 (e.g., non-transitory machine-readable medium, non-transitory machine-readable storage medium, or the like) on which may store instructions 626 encoding any one or more of the methods or functions described herein, including instructions encoding components of FIG. 1 (e.g., predictive component 114, corrective action component 122, model 190, etc.) and for implementing methods described herein. The non-transitory machine-readable storage medium may store instructions which are used to execute methods related to modeling gas dynamics of a process chamber, adjusting processing system operations to improve substrate processing operations, reducing gas backflow to reduce particle deposition, or the like.

Instructions 626 may also reside, completely or partially, within volatile memory 604 and/or within processing device 602 during execution thereof by computer system 600, hence, volatile memory 604 and processing device 602 may also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method, comprising:
providing initial process conditions to a model associated with a process chamber;
providing an indication of one or more adjustments to the process chamber resulting in final process conditions to the model;
obtaining, as first output from the model, an indication of first gas backflow to a substrate support of the process chamber;
generating a first updated one or more adjustments to the process chamber;
providing an indication of the first updated one or more adjustments to the model;
obtaining from the model an indication of second gas backflow to the substrate support; and
perform a corrective action based on the first updated one or more adjustments.

2. The method of claim 1, wherein the model associated with the process chamber comprises a reduced-order physics-based model, based on a computational fluid dynamics model.

3. The method of claim 2, further comprising:
providing a plurality of initial process conditions and a plurality of adjustments as input to the computational fluid dynamics model;
obtaining, as output from the computational fluid dynamics model, a plurality of indications of gas backflow based on the initial process conditions and adjustments;
generating the model based on the input to the computational fluid dynamics model and the output from the computational fluid dynamics model; and
providing an alert to a user indicative of process condition space associated with gas backflow.

4. The method of claim 1, wherein the model associated with the process chamber comprises a trained machine learning model.

5. The method of claim 1, wherein the one or more adjustments comprise one or more of:
adjusting a gas flow into the process chamber;
adjusting a valve opening from the process chamber to an exhaust system; or
adjusting a target gas pressure of the process chamber.

6. The method of claim 1, wherein the updated one or more adjustments comprise increasing a time of actuation of a valve.

7. The method of claim 1, further comprising:
obtaining, as second output from the model, an indication of second gas backflow to a substrate support of the process chamber based on the initial process conditions and the one or more adjustments;
generating second updated one or more adjustments to the process chamber;
providing an indication of second updated one or more adjustments to the model; and
obtaining the indication of first gas backflow based on the second updated one or more adjustments.

8. The method of claim 1, further comprising obtaining, as second output from the model, an indication of a predicted source of particles comprising one or more defects of a substrate of the process chamber.

9. The method of claim 8, further comprising providing particle defect composition data to the model, wherein the second output is based on the particle defect composition data.

10. The method of claim 8, wherein the predicted source comprises one or more of:
a chamber wall of the process chamber;
an etch process byproduct;
a deposition process byproduct; or
an exhaust system of the process chamber.

11. A method, comprising:
obtaining a plurality of initial process conditions associated with a process chamber;
obtaining a plurality of process chamber adjustments;
obtaining a plurality of backflow data, each associated with one of the initial process conditions and one of the process chamber adjustments;
training a machine learning model to predict gas backflow by providing the plurality of initial process conditions and plurality of process chamber adjustments as training input, and the plurality of backflow data as target output.

12. The method of claim 11, wherein the plurality of process chamber adjustments comprises an adjustment to a gas flow into the process chamber, or an adjustment of a valve coupled between the process chamber and an exhaust system.

13. The method of claim 11, further comprising providing the plurality of initial process conditions and the plurality of process chamber adjustments to a physics-based model, wherein the plurality of backflow data is obtained as output from the physics-based model.

14. The method of claim 11, wherein the plurality of process chamber adjustments comprise one or more of:
adjusting a gas flow into the process chamber;
adjusting a valve opening from the process chamber to an exhaust system; or
adjusting a target gas pressure of the process chamber.

15. The method of claim 11, wherein the prediction of gas backflow output by the trained machine learning model comprises an indication of a time of actuation of a valve that achieves a target backflow condition.

16. A non-transitory machine-readable storage medium, storing instruction which, when executed, cause a processing device to perform operations comprising:
providing initial process conditions to a model associated with a process chamber;
providing an indication of one or more adjustments to the process chamber resulting in final process conditions to the model;
obtaining, as first output from the model, an indication of first gas backflow to a substrate support of the process chamber;
generating a first updated one or more adjustments to the process chamber;
providing an indication of the first updated one or more adjustments to the model;
obtaining from the model an indication of second gas backflow to the substrate support; and
perform a corrective action based on the first updated one or more adjustments.

17. The non-transitory machine-readable storage medium of claim 16, wherein the model associated with the process chamber comprises a reduced-order model, generated based on a computational fluid dynamics model, and wherein the operations further comprise:
providing a plurality of initial process conditions and a plurality of adjustments as input to the computational fluid dynamics model;
obtaining, as output from the computational fluid dynamics model, a plurality of indications of gas backflow based on the initial process conditions and adjustments;
generating the model based on the input to the computational fluid dynamics model and the output from the computational fluid dynamics model; and
providing an alert to a user indicative of process condition space associated with gas backflow.

18. The non-transitory machine-readable storage medium of claim 16, wherein the one or more adjustments comprise one or more of:
adjusting a gas flow into the process chamber;
adjusting a valve opening from the process chamber to an exhaust system; or
adjusting a target gas pressure of the process chamber.

19. The non-transitory machine-readable storage medium of claim 16, wherein the operations further comprise:
obtaining, as second output from the model, an indication of second gas backflow to a substrate support of the process chamber based on the initial process conditions and the one or more adjustments;
generating second updated one or more adjustments to the process chamber;
providing an indication of second updated one or more adjustments to the model; and
obtaining the indication of first gas backflow based on the second updated one or more adjustments.

20. The non-transitory machine-readable storage medium of claim 16, further comprising obtaining, as second output from the model, an indication of a predicted source of particles comprising one or more defects of a substrate of the process chamber.
